(19) United States
(12) Patent Application Publication
(10) Pub. No.: US 2020/0407850 A1
(43) Pub. Date: Dec. 31, 2020

(54) FILM FORMING METHOD AND FILM FORMING APPARATUS

(71) Applicants: SUMITOMO HEAVY INDUSTRIES, LTD., Tokyo (JP); KOCHI UNIVERSITY OF TECHNOLOGY, Kochi (JP)

(72) Inventors: Hisashi Kitami, Kanagawa (JP); Tetsuya Yamamoto, Kochi (JP)

(21) Appl. No.: 16/913,784

(22) Filed: Jun. 26, 2020

(30) Foreign Application Priority Data
Jun. 27, 2019 (JP) 2019-119435

(51) Int. Cl. C23C 16/52; C23C 16/448; C23C 16/452

(52) U.S. Cl. CPC C23C 16/52; C23C 16/452; C23C 16/4486

(57) ABSTRACT

A film forming method for forming a zinc oxide film on an object by ionizing oxygen, includes: setting an inflection point at which a relationship between a predetermined characteristic of the zinc oxide film and a proportion of neutral oxygen during film formation changes; determining whether to use a condition of a region where the proportion of neutral oxygen is higher than the inflection point, or to use a condition of a region where the proportion of neutral oxygen is lower than the inflection point; and performing film formation under the determined condition.

### RELATED APPLICATIONS

The content of Japanese Patent Application No. 2019-119435, on the basis of which priority benefits are claimed in an accompanying application data sheet, is in its entirety incorporated herein by reference.

### BACKGROUND

### Technical Field

Certain embodiments of the present invention relate to a film forming method and a film forming apparatus.

### Description of Related Art

As a film forming apparatus for forming a zinc oxide film using a plasma, one disclosed in the related art is known. This film forming apparatus generates a plasma in a chamber using a plasma gun to vaporize a zinc oxide film forming material in the chamber. As zinc oxide adheres onto a substrate, a zinc oxide film is formed on the substrate.

### SUMMARY

According to an embodiment of the present invention, there is provided a film forming method for forming a zinc oxide film on an object by ionizing oxygen, including: setting an inflection point at which a relationship between a predetermined characteristic of the zinc oxide film and a proportion of neutral oxygen during film formation changes; determining whether to use a condition of a region where the proportion of neutral oxygen is higher than the inflection point, or to use a condition of a region where the proportion of neutral oxygen is lower than the inflection point; and performing film formation under the determined condition.

According to another embodiment of the present invention, there is provided a film forming apparatus for forming a zinc oxide film on an object by ionizing oxygen, including: a film forming unit that forms the zinc oxide film; an acquisition unit that acquires an inflection point at which a relationship between a predetermined characteristic of the zinc oxide film and a proportion of neutral oxygen during film formation changes; a detection unit that detects the proportion of the neutral oxygen during the film formation; and a flow rate control unit that controls an oxygen flow rate for the film forming unit such that the proportion of neutral oxygen detected by the detection unit is not allowed to be within a predetermined range with respect to the inflection point.

### BRIEF DESCRIPTION OF THE DRAWINGS

FIG. 1 is a block configuration diagram of a film forming apparatus according to an embodiment of the present invention.

FIG. 2 is a schematic cross-sectional view illustrating a configuration of the film forming apparatus.

FIGS. 3A and 3B are diagrams showing a relationship between various characteristics of a zinc oxide film and a proportion of neutral oxygen.

FIGS. 4A and 4B are diagrams showing a relationship between various characteristics of a zinc oxide film and a proportion of neutral oxygen.

FIG. 5 is a diagram schematically illustrating a structure of the zinc oxide film.

FIG. 6 is a flowchart of a film forming method according to an embodiment of the present invention.

### DETAILED DESCRIPTION

Here, a film forming object on which the zinc oxide film is formed is used for various uses. On the other hand, the characteristics of the zinc oxide film change depending on the conditions during film formation. Therefore, there is a demand for film formation of a zinc oxide film performed under appropriate conditions depending on the use.

It is desirable to provide a film forming method and a film forming apparatus capable of forming a zinc oxide film under appropriate conditions depending on the use.

The film forming method according to the embodiment of the present invention includes the step of setting the inflection point at which the relationship between the predetermined characteristic of the zinc oxide film and the proportion of neutral oxygen during film formation changes. In this case, a change form in the predetermined characteristic with respect to the change in the proportion of neutral oxygen is different between the region where the proportion of neutral oxygen is higher than the inflection point and the region where the proportion of neutral oxygen is lower than the inflection point. The film forming method includes the step of determining whether to use the condition of the region where the proportion of neutral oxygen is higher than the inflection point or to use the condition of the region where the proportion of neutral oxygen is lower than the inflection point. Accordingly, of the condition under which the proportion of neutral oxygen is higher than the inflection point and the condition under which the proportion of neutral oxygen is lower than the inflection point, the more appropriate condition for the use of the zinc oxide film can be set. As described above, the zinc oxide film can be formed under appropriate conditions depending on the use.

The film forming apparatus according to the embodiment of the present invention includes the acquisition unit that acquires the inflection point at which the relationship between the predetermined characteristic of the zinc oxide film and the proportion of neutral oxygen during film formation changes, and the detection unit that detects the proportion of neutral oxygen during film formation. Accordingly, the film forming apparatus can perform film formation under either condition of the region where the proportion of neutral oxygen is higher than the inflection point or the region lower than the inflection point, depending on the use of the zinc oxide film, and during the film formation, can monitor whether the film formation is performed under the corresponding condition by the detection unit. The film forming apparatus also includes the flow rate control unit that controls the oxygen flow rate for the film forming unit such that the proportion of neutral oxygen detected by the detection unit is not allowed to be within the predetermined range with respect to the inflection point. Accordingly, the flow rate control unit can suppress deviation from the condition corresponding to the use of the zinc oxide film. As described above, the zinc oxide film can be formed under appropriate conditions depending on the use.

According to the embodiments of the present invention, the film forming method and the film forming apparatus capable of forming the zinc oxide film under appropriate conditions depending on the use are provided.

Hereinafter, a film forming method and a film forming apparatus according to an embodiment of the present invention will be described with reference to the accompanying drawings. In the description of the drawings, like elements are denoted by like reference symbols, and overlapping descriptions will be omitted.

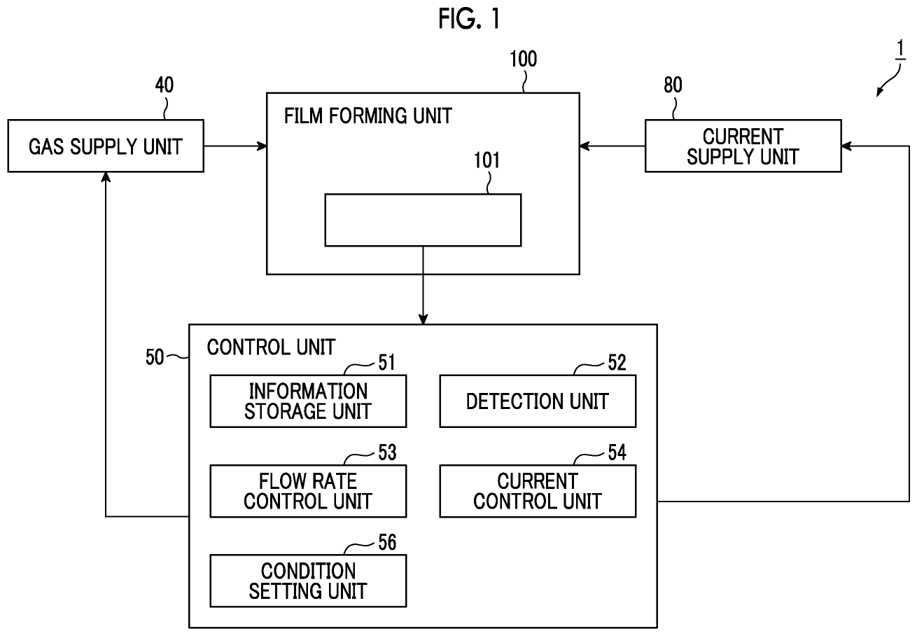

First, the configuration of the film forming apparatus according to the embodiment of the present invention will be described with reference to FIG. 1. FIG. 1 is a block configuration diagram of the film forming apparatus according to the present embodiment. A film forming apparatus 1 is an apparatus that ionizes oxygen to form a zinc oxide film on a substrate. As illustrated in FIG. 1, the film forming apparatus 1 includes a film forming unit 100, a measuring unit 101, a gas supply unit 40, a current supply unit 80, and a control unit 50. The film forming unit 100 forms a film on a substrate. The measuring unit 101 measures spectral data in the film forming unit 100. The gas supply unit 40 supplies a gas to the film forming unit 100. The current supply unit 80 supplies a current for ionizing oxygen to the film forming unit 100. The control unit 50 controls the entire film forming apparatus 1.

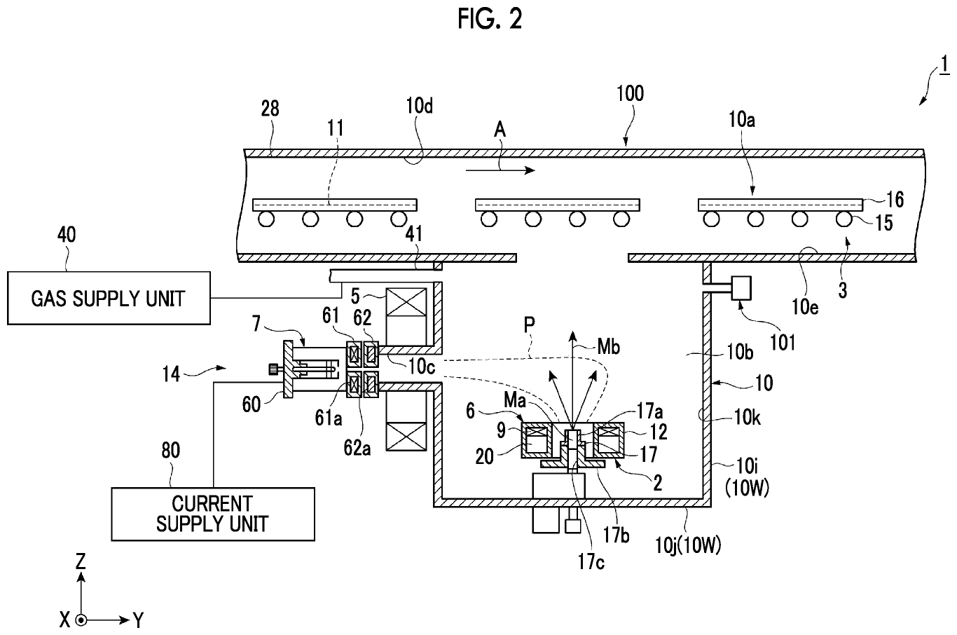

The film forming unit 100, the measuring unit 101, the gas supply unit 40, and the current supply unit 80 will be described with reference to FIG. 2. FIG. 2 is a schematic cross-sectional view illustrating the configuration of the film forming apparatus 1. As illustrated in FIG. 2, the film forming apparatus 1 of the present embodiment is an ion plating apparatus used in a so-called ion plating method. For convenience of description, FIG. 2 shows an XYZ coordinate system. The Y-axis direction is a direction in which a substrate, which will be described later, is transported. The Z-axis direction is a position where the substrate and a hearth mechanism, which will be described later, oppose each other. The X-axis direction is a direction perpendicular to the Y-axis direction and the Z-axis direction.

The film forming apparatus 1 may be a so-called horizontal film forming apparatus in which a substrate 11 is disposed and transported in a vacuum chamber 10 such that the sheet thickness direction of the substrate 11 is substantially vertical. In this case, the X-axis direction and the Y-axis direction are horizontal directions, and the Z-axis direction is the vertical direction and the sheet thickness direction. The film forming apparatus 1 may also be a so-called vertical film forming apparatus in which the substrate 11 is disposed and transported in the vacuum chamber 10 in a state where the substrate 11 is placed upright or inclined from the upright state such that the sheet thickness direction of the substrate 11 is the horizontal direction (Z-axis direction in FIGS. 1 and 2). In this case, the Z-axis direction is the horizontal direction and the sheet thickness direction of the substrate 11, the Y-axis direction is the horizontal direction, and the X-axis direction is the vertical direction. The film forming apparatus according to the embodiment of the present invention will be described below by taking a horizontal film forming apparatus as an example.

The film forming unit 100 includes the vacuum chamber 10, a transporting mechanism 3, and a film forming mechanism 14.

The vacuum chamber 10 is a member for accommodating the substrate 11 and performing a film forming process. The vacuum chamber 10 has a transporting chamber 10a for transporting the substrate 11 on which a film of a film forming material Ma is formed, a film forming chamber 10b for diffusing the film forming material Ma, and a plasma port 10c through which a plasma P irradiated from a plasma gun 7 in a beam shape is received by the vacuum chamber 10. The transporting chamber 10a, the film forming chamber 10b, and the plasma port 10c communicate with each other. The transporting chamber 10a is set along a predetermined transport direction (arrow A in the figure) (along the Y axis). The vacuum chamber 10 is made of a conductive material and is connected to a ground potential.

The film forming chamber 10b has, as a wall portion 10W, a pair of side walls along the transport direction (arrow A), a pair of side walls 10h and 10i along the direction (Z-axis direction) intersecting the transport direction (arrow A), and a bottom wall 10j disposed so as to intersect the X-axis direction.

The transporting mechanism 3 transports a substrate holding member 16 that holds the substrate 11 in a state of facing the film forming material Ma in the transport direction (arrow A). For example, the substrate holding member 16 is a frame body that holds the outer peripheral edge of the substrate 11. The transporting mechanism 3 includes a plurality of transporting rollers 15 installed in the transporting chamber 10a. The transporting rollers 15 are arranged at equal intervals along the transport direction (arrow A), and transport the substrate holding member 16 in the transport direction (arrow A) while supporting the substrate holding member 16. As the substrate 11, a plate-shaped member such as a glass substrate or a plastic substrate is used.

Subsequently, the configuration of the film forming mechanism 14 will be described in detail. The film forming mechanism 14 causes particles of the film forming material Ma to adhere to the substrate 11 by the ion plating method. The film forming mechanism 14 includes the plasma gun 7, a steering coil 5, a hearth mechanism 2, and a wheel hearth 6.

The plasma gun 7 is, for example, a pressure gradient type plasma gun, and has a main body portion connected to the film forming chamber 10b through the plasma port 10c provided in the side wall of the film forming chamber 10b. The plasma gun 7 generates the plasma P in the vacuum chamber 10. The plasma P generated in the plasma gun 7 is emitted in a beam shape from the plasma port 10c into the film forming chamber 10b. Accordingly, the plasma P is generated in the film forming chamber 10b.

One end of the plasma gun 7 is closed by a cathode 60. A first intermediate electrode (grid) 61 and a second intermediate electrode (grid) 62 are concentrically arranged between the cathode 60 and the plasma port 10c. An annular permanent magnet 61a for converging the plasma P is embedded in the first intermediate electrode 61. An electromagnet coil 62a is also embedded in the second intermediate electrode 62 to converge the plasma P.

The steering coil 5 is provided around the plasma port 10c in which the plasma gun is mounted. The steering coil 5 guides the plasma P into the film forming chamber 10b. The steering coil 5 is excited by a power source (not illustrated) for the steering coil.

The hearth mechanism 2 holds the film forming material Ma. The hearth mechanism 2 is provided in the film forming chamber 10b of the vacuum chamber 10 and is disposed in the negative Z-axis direction when viewed from the transporting mechanism 3. The hearth mechanism 2 has a main hearth 17 that is a main anode that guides the plasma P emitted from the plasma gun 7 to the film forming material Ma or a main anode to which the plasma P emitted from the plasma gun 7 is guided.

The main hearth 17 has a tubular filling portion 17a which is filled with the film forming material Ma and extends in the positive Z-axis direction, and a flange portion 17b protruding from the filling portion 17a. Since the main hearth 17 is kept at a positive potential with respect to the ground potential of the vacuum chamber 10, the main hearth 17 serves as an anode in a discharge and attracts the plasma P. A through-hole 17c through which the film forming material Ma is filled is formed in the filling portion 17a of the main hearth 17 on which the plasma P is incident. The tip portion of the film forming material Ma is exposed to the film forming chamber 10b at one end of the through-hole 17c.

A conductive zinc oxide (ZnO) material is used as the film forming material Ma. This conductive material contains zinc oxide as a primary component, and Al₂O₃, B₂O₃, Ga₂O₃, Iu₂O₃, and furthermore B, Al, Si, Ga, In, Ti, Lu, Cu, and the like may be added thereto as additives. Since the film forming material Ma is made of a conductive substance, when the main hearth 17 is irradiated with the plasma P, the plasma P is directly incident on the film forming material Ma and the tip portion of the film forming material Ma is heated to evaporate or sublime, such that film forming material particles Mb ionized by the plasma P diffuse in the film forming chamber 10b. The film forming material particles Mb diffused in the film forming chamber 10b move in the positive Z axis direction in the film forming chamber 10b and adhere to the surface of the substrate 11 in the transporting chamber 10a. The film forming material Ma is a solid material formed into a cylindrical shape having a predetermined length, and the hearth mechanism 2 is filled with a plurality of film forming materials Ma at one time. Then, as the film forming material Ma is consumed, the film forming material Ma is sequentially extruded from the negative Z-direction side of the hearth mechanism 2 so that the tip portion of the film forming material Ma on the foremost side maintains a predetermined positional relationship with the upper end of the main hearth 17.

The wheel hearth 6 is an auxiliary anode having an electromagnet for inducing the plasma P. The wheel hearth 6 is disposed around the filling portion 17a of the main hearth 17 that holds the film forming material Ma. The wheel hearth 6 has an annular coil 9, an annular permanent magnet portion 20, and an annular container 12, and the coil 9 and the permanent magnet portion 20 are accommodated in the container 12. In the present embodiment, the coil 9 and the permanent magnet portion 20 are installed in this order in the negative Z direction when viewed from the transporting mechanism 3, but the permanent magnet portion 20 and the coil 9 may be installed in this order in the negative Z direction. The wheel hearth 6 controls the direction of the plasma P incident on the film forming material Ma or the direction of the plasma P incident on the main hearth 17, depending on the magnitude of the current flowing through the coil 9.

The gas supply unit 40 supplies a carrier gas and an oxygen gas into the vacuum chamber 10. As a substance contained in the carrier gas, for example, a rare gas such as argon or helium is adopted. The gas supply unit 40 is disposed outside the vacuum chamber 10, and supplies a raw material gas into the vacuum chamber 10 through a gas supply port 41 provided on the side wall (for example, the side wall 10h) of the film forming chamber 10b. The gas supply unit 40 supplies a carrier gas and oxygen gas at flow rates based on a control signal from the control unit 50.

The current supply unit 80 supplies a current to the plasma gun 7. Accordingly, the plasma gun 7 performs discharging with a discharge current having a predetermined value. The current supply unit 80 supplies a current having a current value based on a control signal from the control unit 50.

The measuring unit 101 measures spectral data in the vacuum chamber 10. The measuring unit 101 has a function of measuring the light intensity of the plasma in the vacuum chamber 10 for the purpose of measuring the amount of particles in the plasma in the vacuum chamber 10. Specifically, the measuring unit 101 is realized by a configuration including a spectroscope and the like. The measuring unit 101 is provided in the vacuum chamber 10 via a light transmission portion that communicates with the vacuum chamber 10. The measuring unit 101 receives the light of the plasma that has arrived via the light transmission portion. The measuring unit 101 measures light in the vacuum chamber 10 (film forming chamber 10b), particularly in the vicinity of a region where a film is formed on the substrate 11. The light transmission portion may be a straight cylindrical body or an optical fiber.

The particles in the vacuum chamber 10 emit light having an intensity corresponding to the amount at a certain wavelength. Therefore, the measuring unit 101 extracts light at a specific wavelength from the plasma light and measures the intensity thereof by separating light and performing measurement with the spectroscope. Spectral data including information regarding the intensity of light measured by the measuring unit 101 is sent to the control unit 50.

As illustrated in FIG. 1, the control unit 50 is a device that controls the entire film forming apparatus 1, and includes a CPU, a RAM, a ROM, an input/output interface, and the like. The control unit 50 is disposed outside the vacuum chamber 10. The control unit 50 also includes an information storage unit 51, a detection unit 52, a flow rate control unit 53, a current control unit 54, and a condition setting unit 56 (acquisition unit).

The information storage unit 51 stores various kinds of information used for controlling the film forming apparatus 1. The information storage unit 51 stores data indicating the amount of each particle based on the spectral data measured by the measuring unit 101. For example, the information storage unit 51 stores information on the wavelength of neutral oxygen and information on the correspondence relationship between the light intensity at the wavelength and the amount of neutral oxygen. The information storage unit 51 also stores information on oxygen ions (O⁺, O₂⁺).

The information storage unit 51 stores an inflection point at which the relationship between a predetermined characteristic of the zinc oxide film and the proportion of neutral oxygen during film formation changes. In the present embodiment, the proportion of neutral oxygen indicates the proportion of the amount of neutral oxygen to the total amount of neutral oxygen and oxygen ions. The proportion of neutral oxygen is shown by “O/(O+O⁺+2O₂⁺)”.

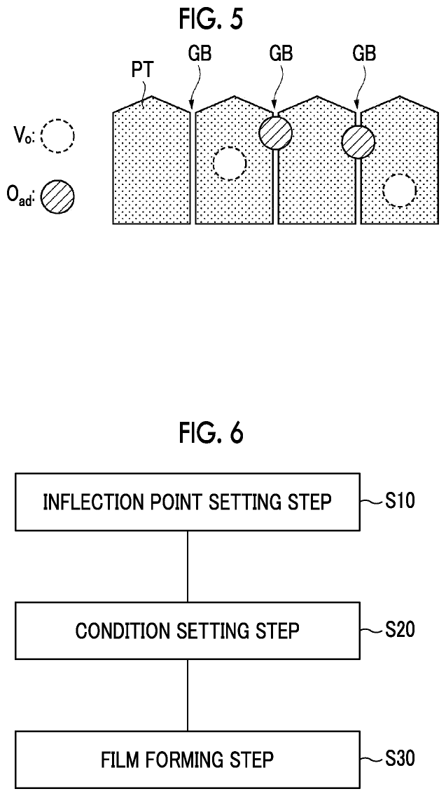

Here, as a result of intensive study, the inventors of the present invention found that by controlling the proportion neutral oxygen during the film formation of the zinc oxide film, a film in which the orientation (parallelism) between columnar crystallites (see FIG. 5, PT in the figure) is aligned, and a film in which the orientation (parallelism) between columnar crystallites (see FIG. 5, PT in the figure) is disoriented, the films having characteristics depending on the application and use of the film forming object, can be produced separately.

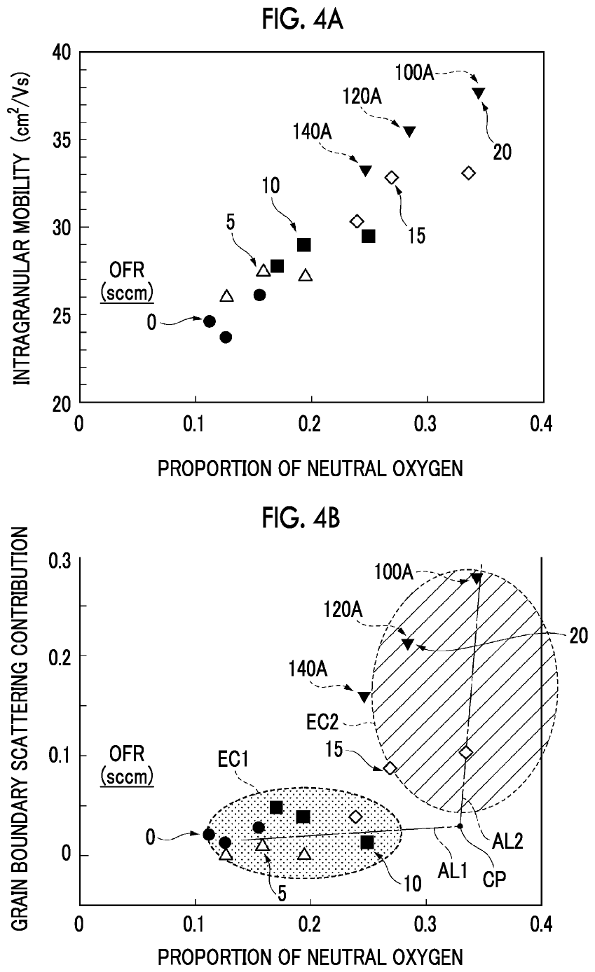

When the orientation (parallelism) between the columnar crystallites (see FIG. 5, PT in the figure) at grain boundaries GB (see FIG. 5) of the zinc oxide film is disturbed, the grain boundary scattering contribution increases, and the carrier mobility at the grain boundaries GB decreases. That is, by controlling the orientation (parallelism) between the columnar crystallites (see FIG. 5, PT in the figure), it becomes possible to control the magnitude of the grain boundary scattering contribution depending on the purpose, and a zinc oxide film that realizes the electrical and optical characteristics required by the application can be obtained. The present inventors found that in a case where a graph showing the relationship between the grain boundary scattering contribution and the proportion of neutral oxygen is set, there is an inflection point at which the relationship between the two (the slope of the graph) changes significantly. Specifically, the present inventors found that in a region (region EC2 in FIG. 4B) where the proportion of neutral oxygen is higher than the inflection point, the increase in the grain boundary scattering contribution is large with respect to the increase in the proportion of neutral oxygen, and in a region (region EC1 in FIG. 4B) where the proportion of neutral oxygen is lower than the inflection point, the increase in the grain boundary scattering contribution is small with respect to the increase in the proportion of neutral oxygen.

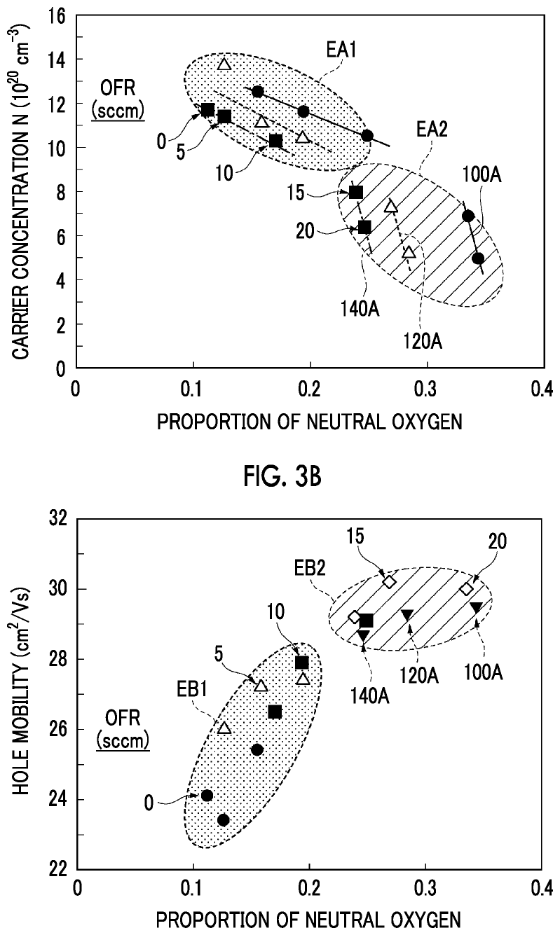

The inflection point will be described with reference to FIGS. 3A to 4B. FIGS. 3A to 4B show results in a case where film formation is performed using the film forming apparatus 1 illustrated in FIG. 2 under conditions of an oxygen flow rate of “0, 5, 10, 15, and 20 (sccm)”, and a discharge current of the plasma gun 7 of “100, 120, and 140 (A)”. In each graph, in a case where the discharge current is under the same condition, the proportion of neutral oxygen increases as the oxygen flow rate increases. In a case where the oxygen flow rate is under the same condition, the proportion of neutral oxygen decreases as the discharge current increases.

FIG. 3A shows the relationship between a carrier concentration of the zinc oxide film and the proportion of neutral oxygen. In FIG. 3A, the dot shape of data is the same under the same discharge current condition. As shown in FIG. 3A, in a region EA1 where the proportion of neutral oxygen is low, the rate of decrease in carrier concentration is small with respect to the increase in the proportion of neutral oxygen. In a region EA2 where the proportion of neutral oxygen is high, the rate of decrease in carrier concentration is large with respect to the increase in the proportion of neutral oxygen.

FIG. 3B shows the relationship between a hole mobility of the zinc oxide film and the proportion of neutral oxygen. The hole mobility is an index showing the ease of movement when electrons move through the entire zinc oxide film 200, and is affected by both the carrier mobility in the columnar crystallites PT and the carrier mobility at the grain boundaries GB. (See FIG. 5). The hole mobility can be measured for the zinc oxide film by using a Hall effect measuring device. In FIG. 3B, the dot shape of data is the same under the same oxygen flow rate condition. As shown in FIG. 3B, in a region EB1 where the proportion of neutral oxygen is low, the rate of increase in hole mobility is large with respect to the increase in the proportion of neutral oxygen. In a region EB2 where the proportion of neutral oxygen is high, the rate of increase in hole mobility is small with respect to the increase in the proportion of neutral oxygen.

FIG. 4A shows the relationship between the columnar crystallite carrier mobility of the zinc oxide film (the vertical axis in FIG. 4A: intragranular mobility) and the proportion of neutral oxygen. The intragranular mobility is an index showing the ease of movement when electrons move inside the columnar crystallites PT of the zinc oxide film 200 (see FIG. 5). The intragranular mobility can be measured by optical measurement of the zinc oxide film. In FIG. 4A, the dot shape of data is the same under the same oxygen flow rate condition. As shown in FIG. 4A, the intragranular mobility increases as the proportion of neutral oxygen increases, regardless of the magnitude of the proportion of neutral oxygen.

FIG. 4B shows the relationship between the grain boundary scattering contribution of the zinc oxide film and the proportion of neutral oxygen. The grain boundary scattering contribution is an index showing the ease of electron scattering at the grain boundaries GB in the zinc oxide film 200 (see FIG. 5). The grain boundary scattering contribution is represented by “μₒₚₜ/μ_{GB}” when the intragranular mobility is “μₒₚₜ” and the intergranular mobility is “μ_{GB}”. The grain boundary scattering contribution can be derived from the relationship among the hole mobility (μ_{H}), intragranular mobility (μₒₚₜ), and intergranular mobility (μ_{GB}). For example, the relationship of Expression 2 can be derived based on Expression 1. In FIG. 4B, the dot shape of data is the same under the same oxygen flow rate condition.

1/μ_{H}=1/μₒₚₜ+1/μ_{GB} (1)

μₒₚₜ/μ_{GB}=(μₒₚₜ−μ_{H})/μ_{H} (2)

As shown in FIG. 4B, in the region EC1 where the proportion of neutral oxygen is low, the rate of increase in the grain boundary scattering contribution is small with respect to the increase in the proportion of neutral oxygen. In the region EC2 where the proportion of neutral oxygen is high, the rate of increase in the grain boundary scattering contribution is large with respect to the increase in the proportion of neutral oxygen. That is, in a case where an inflection point is set between the region EC1 and the region EC2, the condition of the region EC1 where the proportion of neutral oxygen is lower than the inflection point is a condition under which an increase in the grain boundary scattering contribution can be suppressed, that is, a condition under which a highly-oriented zinc oxide film can be formed. The condition is a suitable condition for a case where the zinc oxide film is used for a transparent conductive film. The condition of the region EC2 where the proportion of neutral oxygen is higher than the inflection point is a condition under which the grain boundary scattering contribution can be increased, that is, a condition under which a zinc oxide film having a disordered orientation can be formed. The condition is a suitable condition for a case where the zinc oxide film is used for a functional thin film such as a hydrogen sensor.

A method of setting the inflection point is not particularly limited. For example, dots showing the result when the discharge current is 100 A are extracted, an approximate line AL1 is set for dots having a low grain boundary scattering contribution, and an approximate line AL2 is set for dots having a high grain boundary scattering contribution. At this time, the intersection point between the approximate line AL1 and the approximate line AL2 can be set as an inflection point CP. Similarly, an inflection point in a case where the discharge current is 120 A and an inflection point in a case where the discharge current is 140 A can be set. At this time, the information storage unit 51 stores at least the proportion of neutral oxygen at the inflection point and the discharge current corresponding to the inflection point.

Alternatively, regardless of the discharge current, an approximate line may be set for all dots having low grain boundary scattering contributions, an approximate line may be set for all dots having high grain boundary scattering contributions, and the intersection point between both the approximate lines may be set as the inflection point. The inflection point may be set by other methods.

Returning to FIG. 1, the detection unit 52 detects the proportion of neutral oxygen during film formation. The detection unit 52 detects the proportion of neutral oxygen based on the measurement result of the measuring unit 101 and the data of the information storage unit 51. The detection unit 52 acquires the amount of neutral oxygen by retrieving the spectral data of neutral oxygen from the data of the information storage unit 51. Similarly, the detection unit 52 acquires the amount of “O⁺” and the amount of “O₂⁺”. Accordingly, the detection unit 52 detects the proportion of neutral oxygen (O/(O+O⁺+2O₂⁺)).

The condition setting unit 56 sets film forming conditions. The condition setting unit 56 can set the conditions based on the input by the user. The condition setting unit 56 acquires the inflection point by reading the information of the inflection point from the information storage unit 51. For example, in a case where the user selects the use of zinc oxide, the condition setting unit 56 sets either the condition of the region where the proportion of neutral oxygen is higher than the inflection point and the condition of the region where the proportion of neutral oxygen is lower than the inflection point depending on the selection.

The flow rate control unit 53 controls the flow rate of the gas supplied from the gas supply unit 40 to the film forming unit 100. The flow rate control unit 53 controls the oxygen flow rate for the film forming unit 100 based on the condition set by the condition setting unit 56. In addition, the flow rate control unit 53 may control the oxygen flow rate for the film forming unit 100 such that that the proportion of neutral oxygen detected by the detection unit 52 is not allowed to be within a predetermined range with respect to the inflection point.

The current control unit 54 controls the discharge current supplied by the current supply unit 80 to the film forming unit 100. The current control unit 54 controls the discharge current for the film forming unit 100 based on the condition set by the condition setting unit 56. Furthermore, the current control unit 54 may control the discharge current for the film forming unit 100 such that the proportion of neutral oxygen detected by the detection unit 52 is not allowed to be within a predetermined range with respect to the inflection point.

Next, the film forming method according to the present embodiment will be described with reference to FIG. 6. The film forming method shown in FIG. 6 includes an inflection point setting step S10, a condition setting step S20, and a film forming step S30.

The inflection point setting step S10 is a step of setting the inflection point at which the relationship between the predetermined characteristic of the zinc oxide film and the proportion of neutral oxygen during film formation changes. In the step, the condition setting unit 56 reads the data of the inflection point at which the relationship between the grain boundary scattering contribution and the proportion of neutral oxygen changes from the information storage unit 51, acquires the inflection point, and performs setting. The experimental results shown in FIG. 4B are acquired at a stage before the manufacturing of the film forming apparatus 1. The inflection point obtained based on the experiment result may be obtained at a stage before manufacturing, or the condition setting unit 56 may calculate the inflection point each time from the experiment result.

The condition setting step S20 is a step of determining whether to use the condition of the region where the proportion of neutral oxygen is higher than the inflection point or to use the condition of the region where the proportion of neutral oxygen is lower than the inflection point. The condition setting unit 56 refers to the use of the zinc oxide film selected by the user, and sets the condition that matches the use. In a case where the zinc oxide film is used as a transparent conductive film, the condition setting unit 56 sets the condition of the region where the proportion of neutral oxygen is lower than the inflection point in order to increase the orientation. In a case where the zinc oxide film is used as the functional thin film, the condition setting unit 56 sets the condition of the region where the proportion of neutral oxygen is higher than the inflection point in order to destroy the orientation.

The film forming step S30 is a step of forming a film under the condition determined in the condition setting step S20. The flow rate control unit 53 supplies oxygen gas at a predetermined flow rate to the film forming unit 100, and the current control unit 54 supplies a current of the predetermined flow rate to the plasma gun 7 of the film forming unit 100.

In the film forming step S30, the detection unit 52 may detect the proportion of neutral oxygen during film formation. Furthermore, the flow rate control unit 53 may control the oxygen flow rate for the film forming unit 100 such that that the proportion of neutral oxygen detected by the detection unit 52 is not allowed to be within a predetermined range with respect to the inflection point. For example, when film formation is performed under the condition of the region EC1, in a case where the film formation is performed under a condition that is too close to the inflection point, there is a possibility that the condition may be within the condition of the region EC2 due to the variation in the amount of neutral oxygen and the like. Therefore, a limit value may be set at a position where the proportion of neutral oxygen is lower than the inflection point by a predetermined amount. In this case, when the detection unit 52 detects that the proportion of neutral oxygen is higher than the limit value, the flow rate control unit 53 may reduce the oxygen flow rate to cause the proportion of neutral oxygen to be lower than the limit value.

After an operation of the film forming apparatus 1 is ended, in a case where the zinc oxide film for the same use is formed in the second and subsequent operations, the inflection point setting step S10 and the condition setting step S20 may be omitted in the second and subsequent operations. When a zinc oxide film for a different use is formed, the inflection point setting step S10 and the condition setting step S20 are performed again.

Next, the actions and effects of the film forming method and the film forming apparatus 1 according to the present embodiment will be described.

The film forming method according to the present embodiment includes the step (inflection point setting step S10) of setting the inflection point at which the relationship between the grain boundary scattering contribution of the zinc oxide film and the proportion of neutral oxygen during film formation changes. In this case, a change form in the predetermined characteristic with respect to the change in the proportion of neutral oxygen is different between the region where the proportion of neutral oxygen is higher than the inflection point and the region where the proportion of neutral oxygen is lower than the inflection point. The film forming method includes the step (condition setting step S20) of determining whether to use the condition of the region where the proportion of neutral oxygen is higher than the inflection point or to use the condition of the region where the proportion of neutral oxygen is lower than the inflection point. Accordingly, of the condition under which the proportion of neutral oxygen is higher than the inflection point and the condition under which the proportion of neutral oxygen is lower than the inflection point, the more appropriate condition for the use of the zinc oxide film can be set. As described above, the zinc oxide film can be formed under appropriate conditions depending on the use.

The film forming apparatus 1 according to the present embodiment includes the condition setting unit 56 that acquires the inflection point at which the relationship between the predetermined characteristic of the zinc oxide film and the proportion of neutral oxygen during film formation changes, and the detection unit 52 that detects the proportion of neutral oxygen during film formation. Accordingly, the film forming apparatus 1 can perform film formation under either condition of the region where the proportion of neutral oxygen is higher than the inflection point or the region lower than the inflection point, depending on the use of the zinc oxide film, and during the film formation, can monitor whether the film formation is performed under the corresponding condition by the detection unit 52. The film forming apparatus 1 further includes the flow rate control unit 53 that controls the oxygen flow rate for the film forming unit 100 such that that the proportion of neutral oxygen detected by the detection unit 52 is not allowed to be within the predetermined range with respect to the inflection point. Accordingly, the flow rate control unit 53 can suppress deviation from the condition corresponding to the use of the zinc oxide film. As described above, the zinc oxide film can be formed under appropriate conditions depending on the use.

The present invention is not limited to the above embodiments.

For example, in the above embodiments, the inflection point is set with respect to the grain boundary scattering contribution in FIG. 4B, and the condition is set based on the inflection point. However, depending on the use of the zinc oxide film, an inflection point may be set with respect to the carrier concentration in FIG. 3A, or an inflection point may be set with respect to the hole mobility in FIG. 3B. Furthermore, the conditions set using those inflection points may be used.

In the above embodiments, the ion plating apparatus is used as the film forming unit, but the film forming method of the film forming unit is not particularly limited. For example, a sputtering apparatus as the film forming unit and a film forming method such as a plasma CVD may be employed.

In the above embodiments, in the film forming step S30, the detection unit 52 monitors the proportion of neutral oxygen and controls the oxygen flow rate based on the detection result. However, once the condition is set, the detection by the detection unit 52 and the control of the oxygen flow rate may be omitted in a case where the variation in the proportion of neutral oxygen during film formation is small. In this case, the detection unit 52 may be omitted from the film forming apparatus.

It should be understood that the invention is not limited to the above-described embodiment, but may be modified into various forms on the basis of the spirit of the invention. Additionally, the modifications are included in the scope of the invention.

What is claimed is:

1. A film forming method for forming a zinc oxide film on an object by ionizing oxygen, the method comprising:
setting an inflection point at which a relationship between a predetermined characteristic of the zinc oxide film and a proportion of neutral oxygen during film formation changes;
determining whether to use a condition of a region where the proportion of neutral oxygen is higher than the inflection point, or to use a condition of a region where the proportion of neutral oxygen is lower than the inflection point; and
performing film formation under the determined condition.

2. A film forming apparatus for forming a zinc oxide film on an object by ionizing oxygen, the apparatus comprising:
a film forming unit that forms the zinc oxide film;
an acquisition unit that acquires an inflection point at which a relationship between a predetermined characteristic of the zinc oxide film and a proportion of neutral oxygen during film formation changes;
a detection unit that detects the proportion of the neutral oxygen during the film formation; and
a flow rate control unit that controls an oxygen flow rate for the film forming unit such that the proportion of neutral oxygen detected by the detection unit is not allowed to be within a predetermined range with respect to the inflection point.
